(19) United States
(12) Patent Application Publication
(10) Pub. No.: US 2024/0363371 A1
(43) Pub. Date: Oct. 31, 2024

(54) SUBSTRATE CLEANING IMPROVEMENT

(71) Applicant: Applied Materials, Inc., Santa Clara, CA (US)

(72) Inventors: Edward GOLUBOVSKY, San Jose, CA (US); Steven M. ZUNIGA, Soquel, CA (US); Jagan RANGARAJAN, San Jose, CA (US); Avyay PANCHAPAKESAN, San Jose, CA (US)

(21) Appl. No.: 18/309,314

(22) Filed: Apr. 28, 2023

(51) Int. Cl. H01L 21/67; B08B 1/00; B08B 1/04; H01L 21/02

(52) U.S. Cl. CPC H01L 21/67046; B08B 1/12; B08B 1/32; H01L 21/02052

(57) ABSTRACT

A substrate cleaning apparatus is provided including: a shaft having an outer body and an interior volume, the shaft having a length in a first direction; and a pad carrier assembly comprising: a housing connected to the outer body in a fixed position relative to the outer body of the shaft, the housing having an inner volume; a piston disposed in the inner volume of the housing, the piston movable in the first direction based on pressure changes in the inner volume of the shaft; a pad carrier; and a flexible member connected between the housing and the pad carrier, the flexible member configured to extend or retract in the first direction with the pad carrier based on the pressure changes in the interior volume of the shaft.

### BACKGROUND

Embodiments of the present disclosure generally relate to equipment and methods for improving the cleaning of substrates (e.g., semiconductor substrates) by improving the control of the pressure applied from a cleaning pad on the substrate during the cleaning.

### DESCRIPTION OF THE RELATED ART

Chemical mechanical polishing (CMP) is commonly used in the manufacturing of high-density integrated circuits to planarize or polish a layer of material deposited on a substrate. In a horizontal pre-clean (HPC) module used in a CMP process, a rotating pad is pressed against a material layer on a surface of the substrate, and material is removed across the material layer through a combination of chemical and mechanical activity provided by a cleaning fluid and relative motion of the pad and the substrate. A motor positioned over the pad is used to rotate the pad. The pressure applied by the pad to the substrate can be adjusted by moving the position (e.g., vertical position) of the motor, for example using a sliding mechanism. Due to the varying frictional forces over the useful life of the equipment, it can be difficult to achieve precise and consistent cleaning results when adjusting the pressure applied by the pad in this manner (i.e., adjusting the position of the motor using a sliding mechanism).

Accordingly, there is a need for improved equipment and related methods that can achieve more precise and consistent application of pressure by pads for cleaning substrates during HPC processes and other similar processes.

### SUMMARY

In one embodiment, a substrate cleaning apparatus is provided comprising: a shaft having an outer body and an interior volume, the shaft having a length in a first direction; and a pad carrier assembly comprising: a housing connected to the outer body in a fixed position relative to the outer body of the shaft, the housing having an inner volume; a piston disposed in the inner volume of the housing, the piston movable in the first direction based on pressure changes in the inner volume of the shaft; a pad carrier; and a flexible member connected between the housing and the pad carrier, the flexible member configured to extend or retract in the first direction with the pad carrier based on the pressure changes in the interior volume of the shaft.

In another embodiment, a substrate cleaning apparatus is provided comprising: a shaft having an outer body and an interior volume, the shaft having a length in a first direction; and a pad carrier assembly comprising: a housing connected to the outer body in a fixed position relative to the outer body of the shaft, the housing having an inner volume; a piston disposed in the inner volume of the housing, the piston movable in the first direction; a pad carrier; and a diaphragm positioned between the piston and an upper portion of the housing, the diaphragm configured to create a seal between the interior volume of the shaft and one or more portions of the inner volume of the housing located below the diaphragm.

In another embodiment, a substrate cleaning system comprising: a substrate cleaning apparatus comprising: a substrate support; a shaft having an outer body and an interior volume, the shaft having a length in a first direction; and a pad carrier assembly comprising: a housing connected to the outer body in a fixed position relative to the outer body of the shaft, the housing having an inner volume; a piston disposed in the inner volume of the housing, the piston movable in the first direction; a pad carrier; and a flexible member having an upper portion and a lower portion, the upper portion connected to the housing, and the lower portion connected to the pad carrier; and a controller configured to adjust a pressure in the interior volume of the shaft to stretch the flexible member in the first direction and move the pad carrier closer to the substrate support.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 shows a side cross-sectional view of a cleaning system, according to one embodiment.

FIG. 2 is a side cross-sectional view of the pad carrier positioning system from FIG. 1 and some other components of the cleaning system of FIG. 1, according to one embodiment.

FIG. 3A is a side cross-sectional view of the pad carrier positioning system from FIGS. 1 and 2 showing some additional detail on the pad carrier positioning system, according to one embodiment.

FIG. 3B is a side cross-sectional view of the pad carrier positioning system from FIGS. 1 and 2 showing some additional detail on the pad carrier positioning system, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to equipment and methods for improving the application of pressure to substrates (e.g., semiconductor substrates) during cleaning processes. The improvements are obtained by applying pressure to an interior volume of a shaft that rotates the cleaning pad during the cleaning of the substrate. The pressure applied to the interior volume of the shaft causes a flexible member attached to a pad carrier to stretch like a spring in a downward direction and bring the cleaning pad retained by the pad carrier in contact with the substrate during cleaning. The pressure in the interior volume of the shaft can be adjusted with precision to make fine adjustments to the pressure applied by the cleaning pad to the substrate during cleaning. The flexible member that is configured to stretch like a spring can also be torsionally rigid, so that adjustments to the torque applied to the shaft are independent of the downward pressure applied by the flexible member and translated to the pressure applied by the cleaning pad.

Adjusting the pressure applied by the cleaning pad to the substrate by making adjustments to the pressure applied to the interior volume of the shaft that rotates the cleaning pad is an improvement over conventional cleaning systems that move the motor that rotates the shaft. Due the variation of factors (e.g., frictional forces) during the useful life of conventional cleaning systems, adjusting the pressure applied to a substrate during cleaning using vertical movement of the shaft and motor can be an inconsistent cleaning method. The cleaning systems disclosed herein solve this problem by allowing the vertical position of the shaft and motor to remain stationary while varying the pressure applied to the substrate. Using the cleaning systems disclosed herein, the pressure applied to the substrate during cleaning is adjusted by adjusting the pressure in the interior volume of the shaft that rotates the cleaning pad. The pressure in the interior volume of the shaft can then be used to adjust the pressure applied to the cleaning pad using a diaphragm and a flexible member (e.g., a spring). Using the cleaning systems disclosed herein, the pressure applied to the substrate during can be adjusted with high precision using a near frictionless design, which can produce more consistent and higher quality cleaning results than conventional cleaning systems. Although the following mainly describes an improved system for cleaning substrates (e.g., removing foreign material on a surface of a substrate without scratching the substrate), the benefits of this disclosure can also be applied to buffing (e.g., removing 10-100 Angstroms of layer being buffed) and polishing processes (e.g., CMP processes) to improve the consistency and precision of the pressure applied to the substrate during these processes.

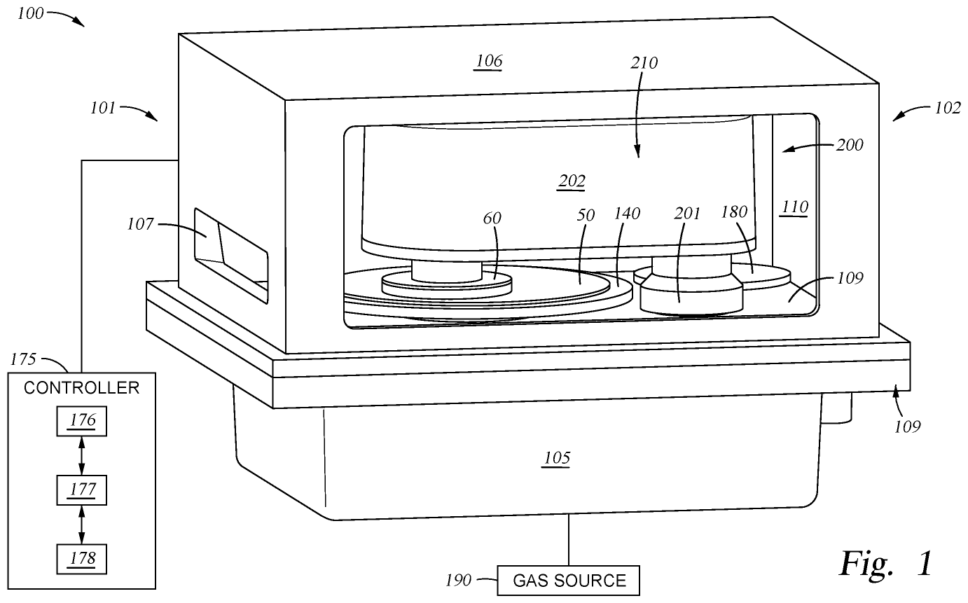

FIG. 1 shows a side cross-sectional view of a cleaning system 100, according to one embodiment. In one embodiment, the cleaning system 100 (also referred to as substrate cleaning system) is a horizontal pre-clean (HPC) system used in a chemical mechanical polishing (CMP) process.

The cleaning system 100 includes a cleaning apparatus 101 (also referred to as substrate cleaning apparatus), a gas source 190, and a controller 175. The cleaning apparatus 101 includes an enclosure 102. The enclosure 102 includes a basin 105 and a lid 106 disposed over the basin 105. The enclosure 102 can include a floor 109 between the lid 106 and the basin 105. A number of components in the cleaning apparatus 101 can be mounted to the floor 109 or positioned to extend through the floor 109. The enclosure 102 encloses an interior volume 110 for cleaning a substrate 50. A sidewall of the lid 106 is removed for illustration purposes to show the components in the interior volume 110. The lid 106 can include a door 107 for transferring substrates 50 to and from the interior volume 110 of the enclosure 102.

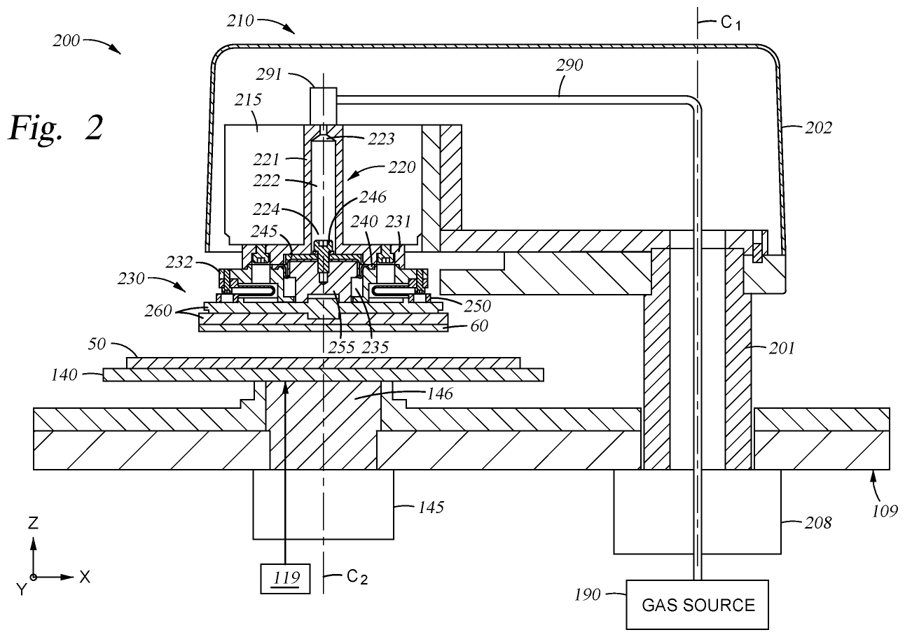

The cleaning apparatus 101 further includes a vacuum table 140 (substrate support) for supporting a substrate 50 during the cleaning. The vacuum table 140 can be coupled to a vacuum pump 119 (see FIG. 2). The vacuum pressure applied to the vacuum table 140 can hold the substrate 50 during the cleaning. Although the substrate support in this disclosure is generally described as a vacuum table, other substrate supports can be used in which other methods of retaining the substrate on the substrate support are used, such as mechanical methods or electrostatic chucking.

The cleaning apparatus 101 further includes a pad carrier positioning system 200. The pad carrier positioning system 200 includes a shaft 201 and a pad carrier positioning arm 210. The shaft 201 can be coupled to an actuator 208 (see FIG. 2) to rotate the pad carrier positioning arm 210 across different portions of the substrate 50 (e.g., different radial positions). The pad carrier positioning arm 210 can include a housing 202. The pad carrier positioning arm 210 can include a pad carrier assembly 230 (see FIG. 2) disposed at least partially in the housing 202 and configured to hold and rotate a cleaning pad 60 across different portions of the substrate 50. As described in further detail below, the pad carrier positioning arm 210 can further include a motor and a shaft positioned at least partially in the housing 202 to rotate the cleaning pad 60 on the substrate 50 to perform the cleaning of the substrate 50. The cleaning apparatus 101 can further include a pad conditioning station 180. The pad carrier positioning arm 210 is configured to move a pad carrier and a cleaning pad 60 from a position over the pad conditioning station 180 to a position over the vacuum table 140.

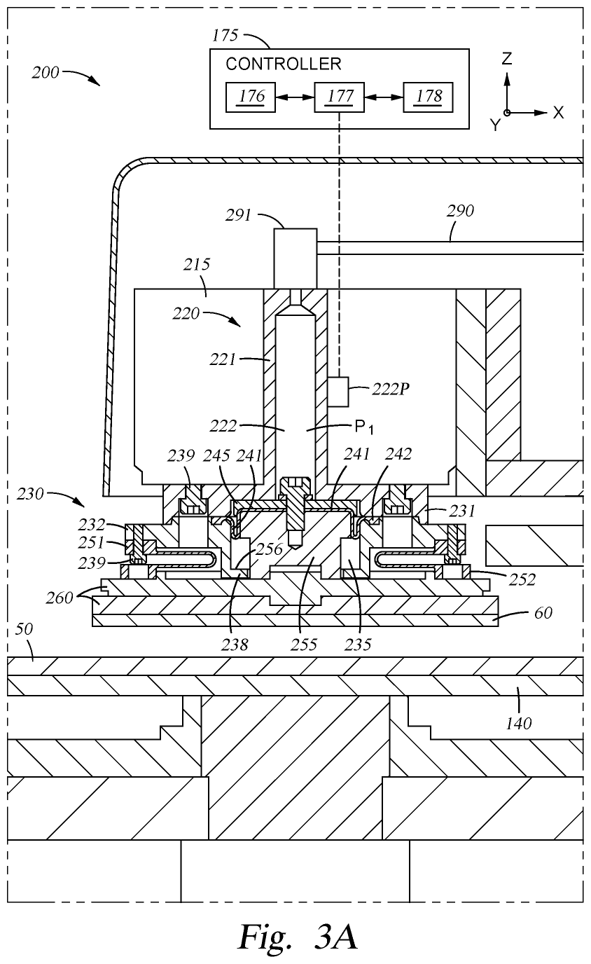

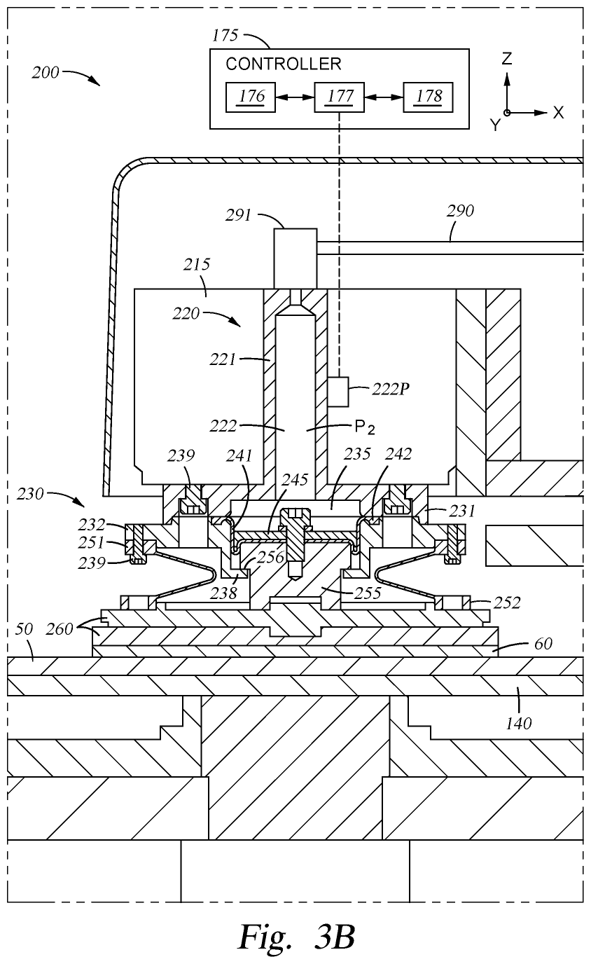

The gas source 190 can be configured to supply pressurized gas to the pad carrier assembly to move the cleaning pad 60 from a position spaced apart from the substrate 50 (see e.g., FIG. 3A) to a position in which the cleaning pad 60 is pressed against the top surface of the substrate 50 (see e.g., FIG. 3B). The controller 175 can use measurements from one or more pressure sensors (see e.g., sensor 222P in FIG. 3A) to adjust the position of one or more valves (not shown) to control the pressure in inner the interior volume of the motor shaft that controls the pressure applied to the cleaning pad 60 and to the substrate 50 during cleaning. In some embodiments, a medium other than gas (e.g., a liquid) can be used to adjust the pressure in the interior of the shaft that controls the pressure applied to the cleaning pad 60 and to the substrate 50 during cleaning.

The cleaning system 100 also includes the controller 175 for controlling processes performed by the cleaning system 100. The controller 175 can be any type of controller used in an industrial setting, such as a programmable logic controller (PLC). The controller 175 includes a processor 177, a memory 176, and input/output (I/O) circuits 178. The controller 175 can further include one or more of the following components (not shown), such as one or more power supplies, clocks, communication components (e.g., network interface card), and user interfaces typically found in controllers for semiconductor equipment.

The memory 176 can include non-transitory memory. The non-transitory memory can be used to store the programs and settings described below. The memory 176 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 177 is configured to execute various programs stored in the memory 176, such as different cleaning processes performed on different substrates 50. During execution of these programs, the controller 175 can communicate to I/O devices through the I/O circuits 178. For example, during execution of these programs and communication through the I/O circuits 178, the controller 175 can control portions of the cleaning process, such as the pressure which the cleaning pad 60 exerts on the substrate 50 during cleaning as described in further detail below. The memory 176 can further include various operational settings used to control the cleaning system 100.

FIG. 2 is a side cross-sectional view of the pad carrier positioning system 200 from FIG. 1 and some other components of the cleaning system 100, according to one embodiment. In FIG. 2, a portion of the housing 202 of the pad carrier positioning arm 210 is removed for illustration purposes to show components located inside the housing 202.

The pad carrier positioning system 200 includes an actuator 208, the shaft 201, and the pad carrier positioning arm 210. In one embodiment, the actuator 208 can be mounted to an underside of the floor 109 of the enclosure 102, and the shaft 201 can extend through the floor 109 to the pad carrier positioning arm 210. The pad carrier positioning arm 210 includes a pad carrier assembly 230 configured to hold a cleaning pad 60 during cleaning. The actuator 208 is configured to rotate the shaft 201 and the pad carrier positioning arm 210 about an axis C1 to move the pad carrier assembly 230 over different portions of the substrate 50 (e.g., different radial locations of the substrate 50) or to other locations, such as over the pad conditioning station 180 (see FIG. 1).

The cleaning apparatus 101 includes the vacuum table 140 and a vacuum pump 119 fluidly coupled to the vacuum table 140. The vacuum pump 119 can apply vacuum pressure to the vacuum table 140 to secure the substrate 50 to the vacuum table 140 during cleaning. The cleaning apparatus 101 can further include an actuator 145 and a shaft 146. In one embodiment, the actuator 145 can be mounted to an underside of the floor 109 of the enclosure 102, and the shaft 146 can extend through the floor 109. The shaft 146 couples the actuator 145 to the vacuum table 140. The actuator can rotate the shaft 146 and the vacuum table 140 about an axis C2 to rotate the substrate 50 on the vacuum table 140 during cleaning.

The pad carrier positioning arm 210 includes a motor 215, a shaft 220, and a pad carrier assembly 230. The cleaning pad 60 can be secured to the pad carrier assembly 230 during cleaning. The motor 215 can be configured to rotate the shaft 220 and the pad carrier assembly 230 about a vertical axis in the Z-direction (first direction). The pad carrier assembly 230 is coupled to the shaft 220. Thus, rotation of the shaft 220 causes rotation of the pad carrier assembly 230 and the cleaning pad 60 secured to the pad carrier assembly 230, so that the substrate 50 can be cleaned by the rotating pad 60.

The shaft 220 includes an outer body 221 disposed around an interior volume 222. The motor 215 is configured to rotate the outer body 221 of the shaft 220. The interior volume 222 can be coupled to the gas source 190 by one or more gas lines 290. The pad carrier positioning arm 210 can also include a rotary union 291 to couple the one or more gas lines 290 to the interior volume 222 to maintain the gas connection as the shaft 220 rotates. The interior volume 222 is coupled to the rotary union 291 at a first end 223 of the interior volume 222 and coupled to the pad carrier assembly 230 at a second end 224 of the interior volume 222. The first end 223 is spaced apart from the second end 224 along a length of the shaft 220 in the Z-direction (first direction). In one embodiment, the one or more gas lines 290 extend from the rotary union 291 through the pad carrier positioning arm 210, through the shaft 201, and to the gas source 190.

The pad carrier assembly 230 includes an upper housing 231 and a lower housing 232. The upper housing 231 can be connected to the outer body 221 of the shaft 220 in a fixed position relative to the outer body 221 of the shaft 220. Thus, rotation of the shaft 220 rotates the upper housing 231. The lower housing 232 can be coupled to the upper housing 231. In some embodiments, the upper housing 231 and the lower housing 232 can be formed of one integral structure. The upper housing 231 and the lower housing 232 can be disposed around an inner volume 235.

The pad carrier assembly 230 can further include a diaphragm 240, a clamp plate 245, and a piston 255. The piston 255 and clamp plate 245 can be positioned inside the inner volume 235 of the upper housing 231 and the lower housing 232. The diaphragm 240 includes an outer portion secured to one or more of the upper housing 231 and the lower housing 232. In one embodiment, the outer portion of the housing is retained (e.g., clamped) between the upper housing 231 and the lower housing 232.

The diaphragm 240 further includes an inner portion 241 (see FIG. 3A) attached to the piston 255. Part of the inner portion 241 of the diaphragm 240 can be attached to the piston 255 by the clamp plate 245. The inner portion 241 of the diaphragm 240 is partially located between the clamp plate 245 and the piston 255. In some embodiments, a fastener 246 can extend through the clamp plate 245, through the inner portion of the diaphragm 240, and into the piston 255 to attach the inner portion 241 of the diaphragm 240 to the piston 255.

When pressure is applied from the gas source 190 to the interior volume 222 of the shaft 220, the clamp plate 245, parts of inner portion 241 (FIG. 3A) of the diaphragm 240, and the piston 255 can move downwards in the Z-direction (first direction) relative to the upper housing 231 and the lower housing 232 to move the cleaning pad 60 closer to the substrate 50 (see FIG. 3B). The diaphragm 240 can be formed of a flexible material, such as rubber or synthetic rubber (e.g., ethylene propylene diene monomer rubber). The diaphragm 240 is configured to create a seal between the interior volume 222 of the shaft 220 and portions of the inner volume 235 below the diaphragm 240. The inner portion 241 (see FIG. 3A) of the diaphragm 240 can deform in response to the increased pressure in the interior volume 222 of the shaft 220 allowing the piston 255 to move downward in the Z-direction while maintaining the seal between the interior volume 222 of the shaft 220 and portions of the inner volume 235 of the housings 231, 232 below the diaphragm 240. As the piston 255 moves downward, the volume of pressurized space above the diaphragm 240 increases and the volume of space in the inner volume 235 below the diaphragm 240 decreases.

The pad carrier assembly 230 can further include a flexible member 250 and a pad carrier 260. The pad carrier 260 is spaced apart from the vacuum table 140 in the Z-direction (first direction). The pad carrier 260 can retain the cleaning pad 60, so that the cleaning pad 60 can be rotated and pressed against the substrate 50 during cleaning of the substrate 50. The pad carrier 260 can be coupled to a lower portion of the flexible member 250. An upper portion of the flexible member 250 can be coupled to the lower housing 232.

The piston 255 and the pad carrier 260 are not rigidly coupled to other components in the pad carrier assembly 230. The lower portion of the piston 255 can move and press against an upper surface of the pad carrier 260 when increased pressure is applied from the gas source 190 to the interior volume 222 of the shaft 220 to apply a downward force in the Z-direction (first direction) that stretches the flexible member 250 in the Z-direction. The stretching of the flexible member 250 in the Z-direction enables the cleaning pad 60 and the pad carrier 260 to move closer to the substrate 50 positioned on the vacuum table 140 and the application of pressure against the substrate 50 after contact between the pad 60 and the substrate 50 is made. In some embodiments, the flexible member 250 can be configured to stretch in the Z-direction from about 2 mm to about 20 mm, such as from about 6 mm to about 8 mm in the Z-direction.

The flexible member 250 (also referred to as a spring) can be formed of an elastic material. In one embodiments, the flexible member 250 can be formed of plastic or metal (e.g., steel) The flexible member 250 can generally be designed to be torsionally rigid with high resistance to deformation brought on by torque forces during the rotation of the pad carrier assembly 230. The torsional rigidity of the flexible member 250 also allows for lateral forces in the XY plane to be transferred from the rotating shaft 220 and through the flexible member 250 and pad carrier 260, which is also torsionally rigid.

On the other hand, the flexible member 250 can be axially flexible in the Z-direction. In some embodiments, the flexible member 250 can function as an extension spring. Increasing pressure in the interior volume 222 can result in a repeatable and precise extension in the Z-direction of the flexible member 250 and pressure applied to the substrate 50 when the cleaning pad 60 contacts the substrate 50 during cleaning of the substrate 50. The flexible member 250 can be described as being more torsionally rigid than axially rigid in the Z-direction. In some embodiments, the flexible member 250 is substantially more torsionally rigid (e.g., at least ten times greater or at least 100 times greater) when compared to the axial rigidity of the flexible member 250 in the Z-direction. For example, a flexible member having a torsional rigidity that is 100 times greater than the axial rigidity of the flexible member can describe a flexible member in which an axial force and a torsional force having a magnitude that is 100 times greater than the axial force can each displace a portion of the flexible member 250 a same distance.

The extension of the flexible member 250 is also a frictionless or near frictionless design that can produce more consistent results for applying pressure to the substrate 50 through the cleaning pad 60 than conventional cleaning systems that move the shaft and/or motor in a vertical direction to adjust the pressure applied to the substrate by the cleaning pad. This movement of the shaft and/or motor in the vertical direction in conventional cleaning systems generally uses components that slide past each other, and the changing frictional properties of these components over time make obtaining consistent results for applying precise amounts of pressure to the cleaning pad during cleaning of a substrate challenging. These problems in conventional cleaning systems can also be a more significant problem for cleaning processes in which the pressure applied to the substrate is relatively low, such as for substrate cleaning processes, because the frictional forces resisting the movement of the sliding elements past each other are of a similar magnitude as the magnitude of the downward forces applied by the cleaning system to achieve the specified pressure for the substrate cleaning process. The cleaning systems disclosed herein also enable cleaning processes to be performed at lower pressures than are typically achievable using conventional cleaning systems.

Having the flexible member 250 be torsionally rigid but flexible in the Z-direction enables the axial pressure in the Z-direction applied to the substrate 50 by the cleaning pad 60 in response to the pressure in the interior volume 222 to be independent of the torque applied to the cleaning pad 60 by the motor 215. Making the axial force in the Z-direction independent of the torque enables finer control over the cleaning process performed by the cleaning system 100 compared to conventional cleaning systems, which can result in higher product quality and more consistent cleaning results over time. Conventional cleaning systems are generally designed to move the motor that rotates the cleaning pad in a vertical direction in order to change the pressure applied by the cleaning pad to the substrate. It is challenging to move a heavy motor in a vertical direction and obtain consistent and precise results for applying pressure to a substrate during cleaning due to variations in frictional forces over the useful life of the cleaning apparatus. This disclosure can solve this problem by allowing the position of the motor 215 to remain stationary while varying the pressure applied to the substrate 50 by the cleaning pad 60 by moving the cleaning pad 60 and/or adjusting the pressure that the cleaning pad applies to the substrate 50 by varying the pressure applied to the interior volume 222 as described above.

In some embodiments, the spring constant of the flexible member 250 is sufficient to retract the cleaning pad 60 and the pad carrier 260 when pressure in the interior volume 222 of the shaft 220 is relieved (e.g., returned to atmospheric pressure). In some embodiments, the flexible member 250 could be mechanically coupled with another spring (not shown) to assist with extending or retracting the pad carrier 260 and pad 60. In some embodiments, a pressure below atmospheric pressure could be applied to the interior volume 222 of the shaft 220 to assist with retracting the pad 60 and the pad carrier 260. The flexible member 250 can also be configured to have a different design in some embodiments. For example, in one embodiment a bellows can be used to perform the functions of the flexible member 250 described herein.

FIG. 3A is a side cross-sectional view of the pad carrier positioning system 200 from FIGS. 1 and 2 showing some additional detail on the pad carrier positioning system 200, according to one embodiment. In FIG. 3A, the cleaning pad 60 is positioned away from the substrate 50.

In some embodiments, the pad carrier positioning system 200 can include a pressure sensor 222P positioned to measure a pressure of the interior volume 222 of the shaft 220. In other embodiments, a pressure sensor can be positioned at another location, such as along one of the gas lines 290. In FIG. 3A, a pressure P1 in the interior volume 222 measured by the pressure sensor 222P is a low pressure, such as atmospheric pressure. The controller 175 can adjust the position of one or more valves (not shown) to achieve the low pressure P1, for example by closing one or more valves connected to the supply of the gas source 190 (see FIG. 1) and venting the gas lines 290 and interior volume 222 to atmosphere. At low pressures, the flexible member 250 relaxes, the piston 255 moves up to the position shown in FIG. 3A, and the pad carrier 260 and cleaning pad 60 are spaced apart from the substrate 50. As shown in FIG. 3A, a lower portion 252 of the flexible member 250 is close to an upper portion 251 of the flexible member 250. The upper portion 251 of the flexible member 250 is attached to the lower housing 232. The lower portion 252 of the flexible member 250 is connected to the pad carrier 260.

Furthermore, at low pressures (e.g., P1), the piston 255 is in a raised position in the inner volume 235 of the housings 231, 232. An inner portion 241 of the diaphragm 240 is located between the clamp plate 245 and the piston 255. An outer portion 242 of the diaphragm 240 is retained (e.g., clamped) in a stationary position between the upper housing 231 and the lower housing 232. The lower housing 232 can include a hard stop 238 that prevents the diaphragm 241 and flexible member 250 from accidental excessive displacement under pressure when the pad carrier positioning arm 210 is not over the substrate 50 or pad conditioning station 180. Thus, the hard stop 238 is configured to prevent damage to the diaphragm 241 and/or flexible member 250. The pad carrier assembly 230 can also include a plurality of fasteners 239 connecting some of the different components in the pad carrier assembly 230 to each other. For example, in one embodiment, fasteners 239 can connect the upper portion 251 of the flexible member 250 to the lower housing 232. The connection of the upper portion 251 of the flexible member 250 to the lower housing 232 and the connection of the lower portion 252 of the flexible member 250 to the pad carrier 260 is one example of how a flexible member can be configured to assist with extending and retracting the pad carrier 260 and pad 60 when the pressure is changed in the interior volume 222 of the shaft 220. More generally, the flexible member 250 is configured to translate the pressure in the interior volume 222 of the shaft 220 to axial movement of the pad carrier 260 and the cleaning pad 60 in the Z-direction (first direction), so that the pad carrier 260 and pad 60 can be pressed against the substrate 50 and pressure can be applied against the substrate 50 during cleaning (see FIG. 3B) and the pad carrier 260 and the pad 60 can be retracted away from the substrate 50 (see FIG. 3A).

FIG. 3B is a side cross-sectional view of the pad carrier positioning system 200 from FIGS. 1 and 2 showing some additional detail on the pad carrier positioning system 200, according to one embodiment. In FIG. 3B, the cleaning pad 60 is positioned against the substrate 50.

In FIG. 3B, a pressure P2 in the interior volume 222 measured by the pressure sensor 222P is a higher pressure, such as a pressure greater than atmospheric pressure. The controller 175 can adjust the position of one or more valves (not shown) connected to the gas source 190 (see FIG. 1) to achieve the higher pressure P2. At higher pressures, the flexible member 250 extends and the pad carrier 260 and cleaning pad 60 are positioned closer to or against the substrate 50. The pressure in the interior volume 222 can be increased from the pressure P1 (e.g., atmospheric pressure) shown in FIG. 3A to higher pressures at which the cleaning pad 60 contacts the substrate 50 with a light pressure, and then the pressure in the interior volume 222 can be increased further to have the cleaning pad 60 apply a specified amount of pressure to the substrate 50 during cleaning.

As shown in FIG. 3B, the lower portion 252 of the flexible member 250 is spaced apart from the upper portion 251 of the flexible member 250 by a greater distance in the Z-direction than in FIG. 3A due to the higher pressure P2 in the interior volume 222 in FIG. 3B compared to the lower pressure P1 in the interior volume 222 in FIG. 3A. In FIG. 3B, the piston 255 is in a lowered position in the inner volume 235 of the housings 231, 232. As the piston 255 lowers in the inner volume 235, a part of the inner portion 241 of the diaphragm 240 rolls over an inner wall of the lower housing 232, and the seal between the interior volume 222 and portions of the inner volume 235 below the diaphragm 240 is maintained.

The piston 255 can include an outer rim 256 configured to contact the hard stop 238 when the pressure in the inner volume 235 is raised to a level that causes the flexible member 250 to stretch far enough in the Z-direction to allow the outer rim 256 to contact the hard stop 238. The hard stop 238 is configured to prevent further movement of the pad carrier 260 and cleaning pad 60 in the Z-direction (first direction), which can prevent damage to the substrate 50 and vacuum table 140.

While the foregoing is directed to examples of the present disclosure, other and further examples of the disclosure may be devised without departing from the basic scope thereof, and the scope thereof is determined by the claims that follow.

What is claimed is:

1. A substrate cleaning apparatus comprising:
a shaft having an outer body and an interior volume, the shaft having a length in a first direction; and
a pad carrier assembly comprising:
a housing connected to the outer body in a fixed position relative to the outer body of the shaft, the housing having an inner volume;
a piston disposed in the inner volume of the housing, the piston movable in the first direction based on pressure changes in the interior volume of the shaft;
a pad carrier; and
a flexible member connected between the housing and the pad carrier, the flexible member configured to extend or retract in the first direction with the pad carrier based on the pressure changes in the interior volume of the shaft.

2. The substrate cleaning apparatus of claim 1, wherein the piston is configured to apply a force on the pad carrier in the first direction to stretch the flexible member in the first direction.

3. The substrate cleaning apparatus of claim 1, further comprising a motor configured to rotate the shaft and the pad carrier assembly.

4. The substrate cleaning apparatus of claim 1, further comprising a diaphragm positioned between the piston and an upper portion of the housing, the diaphragm configured to create a seal between the interior volume of the shaft and one or more portions of the inner volume of the housing located below the diaphragm.

5. The substrate cleaning apparatus of claim 4, wherein an outer portion of the diaphragm is connected to the housing and an inner portion of the diaphragm is configured to deform and cause the piston to move in the first direction in response to increased pressure in the interior volume of the shaft.

6. The substrate cleaning apparatus of claim 5, wherein the inner portion of the diaphragm is attached to the piston.

7. The substrate cleaning apparatus of claim 1, further comprising a rotary union connected to a first end of the interior volume of the shaft.

8. The substrate cleaning apparatus of claim 1, further comprising a vacuum table configured to support a substrate, the vacuum table spaced apart from the pad carrier in the first direction.

9. The substrate cleaning apparatus of claim 1, wherein the pad carrier assembly includes a hard stop configured to prevent further movement of the pad carrier in the first direction.

10. The substrate cleaning apparatus of claim 1, wherein the flexible member includes an upper portion and a lower portion, the upper portion connected to the housing, and lower portion connected to the pad carrier.

11. The substrate cleaning apparatus of claim 1, wherein the flexible member is more torsionally rigid than axially rigid.

12. The substrate cleaning apparatus of claim 1, wherein the flexible member is at least ten times more torsionally rigid than axially rigid.

13. A substrate cleaning apparatus comprising:
a shaft having an outer body and an interior volume, the shaft having a length in a first direction; and
a pad carrier assembly comprising:
a housing connected to the outer body in a fixed position relative to the outer body of the shaft, the housing having an inner volume;
a piston disposed in the inner volume of the housing, the piston movable in the first direction;
a pad carrier; and
a diaphragm positioned between the piston and an upper portion of the housing, the diaphragm configured to create a seal between the interior volume of the shaft and one or more portions of the inner volume of the housing located below the diaphragm.

14. The substrate cleaning apparatus of claim 13, wherein an outer portion of the diaphragm is connected to the housing and an inner portion of the diaphragm is configured to deform and cause the piston to move in the first direction in response to increased pressure in the interior volume of the shaft.

15. The substrate cleaning apparatus of claim 14, wherein the inner portion of the diaphragm is attached to the piston.

16. The substrate cleaning apparatus of claim 15, further comprising a flexible member having an upper portion and a lower portion, the upper portion connected to the housing, and lower portion connected to the pad carrier.

17. The substrate cleaning apparatus of claim 16, wherein the piston is configured to apply a force on the pad carrier in the first direction to stretch the flexible member in the first direction.

18. The substrate cleaning apparatus of claim 13, wherein the pad carrier assembly includes a hard stop configured to prevent further movement of the pad carrier in the first direction.

19. A substrate cleaning system comprising:
a substrate cleaning apparatus comprising:
a substrate support;
a shaft having an outer body and an interior volume, the shaft having a length in a first direction; and
a pad carrier assembly comprising:
a housing connected to the outer body in a fixed position relative to the outer body of the shaft, the housing having an inner volume;
a piston disposed in the inner volume of the housing, the piston movable in the first direction;
a pad carrier; and
a flexible member having an upper portion and a lower portion, the upper portion connected to the housing, and the lower portion connected to the pad carrier; and
a controller configured to adjust a pressure in the interior volume of the shaft to stretch the flexible member in the first direction and move the pad carrier closer to the substrate support.

20. The substrate cleaning system of claim 19, further comprising:
a motor configured to rotate the shaft and the pad carrier assembly; and
a diaphragm positioned between the piston and an upper portion of the housing, the diaphragm configured to create a seal between the interior volume of the shaft and one or more portions of the inner volume of the housing located below the diaphragm.
